(19) United States
(12) Patent Application Publication
(10) Pub. No.: US 2026/0229286 A1
(43) Pub. Date: Aug. 6, 2026

(54) STORAGE DEVICE

(71) Applicant: SONY SEMICONDUCTOR SOLUTIONS CORPORATION, KANAGAWA (JP)

(72) Inventors: KEIZO HIRAGA, KANAGAWA (JP); LUI SAKAI, KANAGAWA (JP); YUTAKA HIGO, KANAGAWA (JP); MASANORI HOSOMI, KANAGAWA (JP)

(21) Appl. No.: 19/154,385

(22) PCT Filed: Jan. 9, 2024
(86) PCT No.: PCT/JP2024/000141

§ 371 Date: Aug. 7, 2025

(30) Foreign Application Priority Data
Mar. 1, 2023 (JP) 2023-030743

(51) Int. Cl. G11C 14/00; G11C 11/16; G11C 11/412

(52) U.S. Cl. CPC G11C 14/0081; G11C 11/161; G11C 11/1675; G11C 11/412

(57) ABSTRACT

Data retained in a volatile storage unit can be stored in a nonvolatile storage unit on the basis of voltage drive. The storage device includes a volatile storage unit that complementarily retains data, a voltage controlled magnetoresistive effect element that retains the data complementarily retained in the volatile storage unit, a first variable resistance element that is connected between the volatile storage unit and the voltage controlled magnetoresistive effect element and has a variable resistance between the volatile storage unit and the voltage controlled magnetoresistive effect element, and a second variable resistance element that is connected between the volatile storage unit and the voltage controlled magnetoresistive effect element with an inverter interposed therebetween and has a variable resistance between the volatile storage unit and the voltage controlled magnetoresistive effect element.

### TECHNICAL FIELD

The present technology relates to a storage device. More particularly, the present technology relates to a storage device in which a nonvolatile storage unit is provided in a volatile storage unit.

### BACKGROUND ART

There is a storage device in which a nonvolatile storage unit is added to a memory cell in which a volatile storage unit is provided in order to prevent data retained in the volatile storage unit from being lost even though a power supply abnormality or a power supply interruption occurs. As such a storage device, for example, there is a technology of writing data retained by a flip-flop unit to the nonvolatile storage unit in a case where data stored in the nonvolatile storage unit and the data retained by the flip-flop unit are not the same (see, for example, Patent Document 1).

### CITATION LIST

### Patent Document

Patent Document 1: Japanese Patent Application Laid-Open No. 2019-50068

### SUMMARY OF THE INVENTION

### Problems to be Solved by the Invention

However, in the above-described related art, in a case where data is to be stored in nonvolatile elements, the nonvolatile elements are driven by currents, and currents in opposite orientations from each other flow in the nonvolatile elements in accordance with data to be stored. Thus, depending on the nonvolatile elements, current flowing at the time of storing data may increase, leading to an increase in power consumption.

The present technology has been made in view of such a situation, and an object of the present technology is to enable data retained in a volatile storage unit to be stored in a nonvolatile storage unit on the basis of voltage drive.

### Solutions to Problems

The present technology has been made to solve the above-described problems, and a first aspect thereof is a storage device including a volatile storage unit that complementarily retains data, a voltage controlled magnetoresistive effect element that retains the data complementarily retained in the volatile storage unit, a first variable resistance element that is connected between the volatile storage unit and the voltage controlled magnetoresistive effect element and has a variable resistance between the volatile storage unit and the voltage controlled magnetoresistive effect element, and a second variable resistance element that is connected between the volatile storage unit and the voltage controlled magnetoresistive effect element with an inverter interposed therebetween and has a variable resistance between the volatile storage unit and the voltage controlled magnetoresistive effect element. This brings about an effect that the data retained in the volatile storage unit is stored in the nonvolatile storage unit on the basis of voltage drive.

Furthermore, in the first aspect, the second variable resistance element and the inverter may be connected in series, and a series circuit of the second variable resistance element and the inverter may be connected in parallel with the first variable resistance element. This brings about an effect that the data is complementarily stored in the nonvolatile storage unit while the complementarity of the data retained in the volatile storage unit is reflected.

Furthermore, in the first aspect, each of the first variable resistance element and the second variable resistance element may change a resistance such that cell voltages applied to the voltage controlled magnetoresistive effect element become substantially equal to each other between when the voltage controlled magnetoresistive effect element transitions from a high resistance state to a low resistance state and when the voltage controlled magnetoresistive effect element transitions from the low resistance state to the high resistance state. This brings about an effect that data is written to the voltage controlled magnetoresistive effect element on the basis of the cell voltage having the same polarity applied to the voltage controlled magnetoresistive effect element.

Furthermore, in the first aspect, the first variable resistance element may include a first field effect transistor of which an on-resistance changes on a basis of a first gate voltage, and the second variable resistance element may include a second field effect transistor of which an on-resistance changes on a basis of a second gate voltage. This brings about an effect that writing in the low resistance state and the high resistance state of the voltage controlled magnetoresistive effect element is performed on the basis of the first gate voltage and the second gate voltage.

Furthermore, in the first aspect, the first field effect transistor may be used not only as the first variable resistance element but also as a storing transistor that stores data from the volatile storage unit to the voltage controlled magnetoresistive effect element and a restoring transistor that restores data from the voltage controlled magnetoresistive effect element to the volatile storage unit. This brings about an effect that it is possible to perform storing and restoring between the voltage controlled magnetoresistive effect element and the volatile storage unit while achieving simplification of a circuit configuration.

Furthermore, in the first aspect, the voltage controlled magnetoresistive effect element may include a first voltage controlled magnetoresistive effect element and a second voltage controlled magnetoresistive effect element in which resistance states different from each other are set in accordance with the data complementarily retained in the volatile storage unit. This brings about an effect that the data is complementarily stored in the nonvolatile storage unit while the complementarity of the data retained in the volatile storage unit is reflected.

Furthermore, in the first aspect, in a case where the first voltage controlled magnetoresistive effect element is written with a high resistance on a basis of a first gate voltage applied to the first field effect transistor, the second voltage controlled magnetoresistive effect element may be written with a low resistance on a basis of a second gate voltage applied to the second field effect transistor. This brings about an effect that data is written to the voltage controlled magnetoresistive effect element on the basis of the VCMA effect.

Furthermore, in the first aspect, in a case where the first voltage controlled magnetoresistive effect element is in a low resistance state when high-resistance writing is performed, a reversal voltage for reversing a magnetization direction of the first voltage controlled magnetoresistive effect element may be applied to the first voltage controlled magnetoresistive effect element on a basis of the first gate voltage, in a case where the first voltage controlled magnetoresistive effect element is in a high resistance state when high-resistance writing is performed, a voltage higher than the reversal voltage may be applied to the first voltage controlled magnetoresistive effect element on a basis of the first gate voltage, in a case where the second voltage controlled magnetoresistive effect element is in a high resistance state when low-resistance writing is performed, a reversal voltage for reversing a magnetization direction of the second voltage controlled magnetoresistive effect element may be applied to the second voltage controlled magnetoresistive effect element on a basis of the second gate voltage, and in a case where the second voltage controlled magnetoresistive effect element is in a low resistance state when low-resistance writing is performed, a voltage lower than the reversal voltage may be applied to the second voltage controlled magnetoresistive effect element on a basis of the second gate voltage. This brings about an effect that the resistance state of the first voltage controlled magnetoresistive effect element is reversed in accordance with the resistance state of the first voltage controlled magnetoresistive effect element and the resistance state of the second voltage controlled magnetoresistive effect element is reversed in accordance with the resistance state of the second voltage controlled magnetoresistive effect element.

Furthermore, in the first aspect, in a case where the first voltage controlled magnetoresistive effect element is written with a low resistance on a basis of a first gate voltage applied to the first field effect transistor, the second voltage controlled magnetoresistive effect element may be written with a high resistance on a basis of a second gate voltage applied to the second field effect transistor. This brings about an effect that data is written to the voltage controlled magnetoresistive effect element on the basis of the VCMA effect.

Furthermore, in the first aspect, in a case where the first voltage controlled magnetoresistive effect element is in a high resistance state when low-resistance writing is performed, a reversal voltage for reversing a magnetization direction of the first voltage controlled magnetoresistive effect element may be applied to the first voltage controlled magnetoresistive effect element on a basis of the first gate voltage, in a case where the first voltage controlled magnetoresistive effect element is in a low resistance state when low-resistance writing is performed, a voltage lower than the reversal voltage may be applied to the first voltage controlled magnetoresistive effect element on a basis of the first gate voltage, in a case where the second voltage controlled magnetoresistive effect element is in a low resistance state when high-resistance writing is performed, a reversal voltage for reversing a magnetization direction of the second voltage controlled magnetoresistive effect element may be applied to the second voltage controlled magnetoresistive effect element on a basis of the second gate voltage, and in a case where the second voltage controlled magnetoresistive effect element is in a high resistance state when high-resistance writing is performed, a voltage higher than the reversal voltage may be applied to the second voltage controlled magnetoresistive effect element on a basis of the second gate voltage. This brings about an effect that the resistance state of the first voltage controlled magnetoresistive effect element is reversed in accordance with the resistance state of the first voltage controlled magnetoresistive effect element and the resistance state of the second voltage controlled magnetoresistive effect element is reversed in accordance with the resistance state of the second voltage controlled magnetoresistive effect element.

Furthermore, in the first aspect, each of the first voltage controlled magnetoresistive effect element and the second voltage controlled magnetoresistive effect element may include a pinned layer having a fixed magnetization direction, free layer capable of reversing a magnetization direction of magnetism induced on a basis of a voltage, and a tunnel barrier layer sandwiched between the pinned layer and the free layer. This brings about an effect that the magnetization direction of the voltage controlled magnetoresistive effect element is reversed on the basis of voltage drive.

Furthermore, in the first aspect, in a case where data is stored from the volatile storage unit to the voltage controlled magnetoresistive effect element, a drive voltage may be applied to the free layer of the first voltage controlled magnetoresistive effect element such that the reversal voltage is applied when the first gate voltage is applied to the first field effect transistor, the drive voltage may be applied to the free layer of the second voltage controlled magnetoresistive effect element such that the reversal voltage is applied when the second gate voltage is applied to the second field effect transistor, and in a case where data is restored from the voltage controlled magnetoresistive effect element to the volatile storage unit, a voltage lower than a voltage applied to the pinned layer may be applied to the free layer. This brings about an effect that data is stored on the basis of the VCMA effect and the data is restored without destroying the data retained in the voltage controlled magnetoresistive effect element.

Furthermore, in the first aspect, in a case where data is stored from the volatile storage unit to the voltage controlled magnetoresistive effect element, a drive voltage may be applied to the pinned layer of the first voltage controlled magnetoresistive effect element such that the reversal voltage is applied when the first gate voltage is applied to the first field effect transistor, the drive voltage may be applied to the pinned layer of the second voltage controlled magnetoresistive effect element such that the reversal voltage is applied when the second gate voltage is applied to the second field effect transistor, and in a case where data is restored from the voltage controlled magnetoresistive effect element to the volatile storage unit, a voltage lower than a voltage applied to the free layer may be applied to the pinned layer. This brings about an effect that data is stored on the basis of the VCMA effect and the data is restored without destroying the data retained in the voltage controlled magnetoresistive effect element.

Furthermore, in the first aspect, in a case where data is stored from the volatile storage unit to the voltage controlled magnetoresistive effect element, the drive voltage may be set such that voltages in a same direction are applied to the first voltage controlled magnetoresistive effect element and the second voltage controlled magnetoresistive effect element. This brings about an effect that data is stored from the volatile storage unit to the voltage controlled magnetoresistive effect element on the basis of the VCMA effect.

Furthermore, in the first aspect, the storage device may further include a power gating transistor that performs power gating of the inverter. This brings about an effect that the data retained in the voltage controlled magnetoresistive effect element is restored in the volatile storage unit.

Furthermore, in the first aspect, the volatile storage unit may be a latch circuit. This brings about an effect that a nonvolatile storage function is added to the latch circuit.

Furthermore, in the first aspect, the volatile storage unit may be a static random access memory (SRAM). This brings about an effect that a nonvolatile storage function is added to the SRAM.

### BRIEF DESCRIPTION OF DRAWINGS

FIG. 1 is a diagram illustrating a configuration example of a storage device according to a first embodiment.

FIG. 2 is a diagram illustrating a first example of a first storing operation of the storage device according to the first embodiment.

FIG. 3 is a diagram illustrating a first example of a second storing operation of the storage device according to the first embodiment.

FIG. 4 is a timing chart illustrating a first example of a storing timing of the storage device according to the first embodiment.

FIG. 5 is a diagram illustrating a second example of the first storing operation of the storage device according to the first embodiment.

FIG. 6 is a diagram illustrating a second example of the second storing operation of the storage device according to the first embodiment.

FIG. 7 is a timing chart illustrating a second example of the storing timing of the storage device according to the first embodiment.

FIG. 8 is a diagram illustrating an example of a restoring operation of the storage device according to the first embodiment.

FIG. 9 is a timing chart illustrating an example of a restoring timing of the storage device according to the first embodiment.

FIG. 10 is a timing chart illustrating a first example of a storing timing of a storage device according to a second embodiment.

FIG. 11 is a timing chart illustrating a second example of the storing timing of the storage device according to the second embodiment.

FIG. 12 is a timing chart illustrating an example of a restoring timing of the storage device according to the second embodiment.

FIG. 13 is a diagram illustrating a configuration example of a storage device according to a third embodiment.

FIG. 14 is a timing chart illustrating a first example of a storing timing of the storage device according to the third embodiment.

FIG. 15 is a timing chart illustrating a second example of the storing timing of the storage device according to the third embodiment.

FIG. 16 is a timing chart illustrating a first example of a storing timing of a storage device according to a fourth embodiment.

FIG. 17 is a timing chart illustrating a second example of the storing timing of the storage device according to the fourth embodiment.

FIG. 18 is a block diagram illustrating an overall configuration example of a storage device according to a fifth embodiment.

FIG. 19 is a diagram illustrating a configuration example of a memory cell of the storage device according to the fifth embodiment.

### MODE FOR CARRYING OUT THE INVENTION

Modes for carrying out the present technology (hereinafter, referred to as embodiments) will be described below. The description will be given in the following order.

1. First embodiment (example in which voltage controlled magnetoresistive effect element is provided in latch circuit, drive voltage is applied to free layer of voltage controlled magnetoresistive effect element and forward logic of latch circuit is stored in voltage controlled magnetoresistive effect element)

2. Second embodiment (example in which voltage controlled magnetoresistive effect element is provided in latch circuit, drive voltage is applied to free layer of voltage controlled magnetoresistive effect element and reverse logic of latch circuit is stored in voltage controlled magnetoresistive effect element)

3. Third embodiment (example in which voltage controlled magnetoresistive effect element is provided in latch circuit, drive voltage is applied to pinned layer of voltage controlled magnetoresistive effect element and forward logic of latch circuit is stored in voltage controlled magnetoresistive effect element)

4. Fourth embodiment (example in which voltage controlled magnetoresistive effect element is provided in latch circuit, drive voltage is applied to pinned layer of voltage controlled magnetoresistive effect element and reverse logic of latch circuit is stored in voltage controlled magnetoresistive effect element)

5. Fifth embodiment (example in which voltage controlled magnetoresistive effect element is provided in SRAM)

### 1. First Embodiment

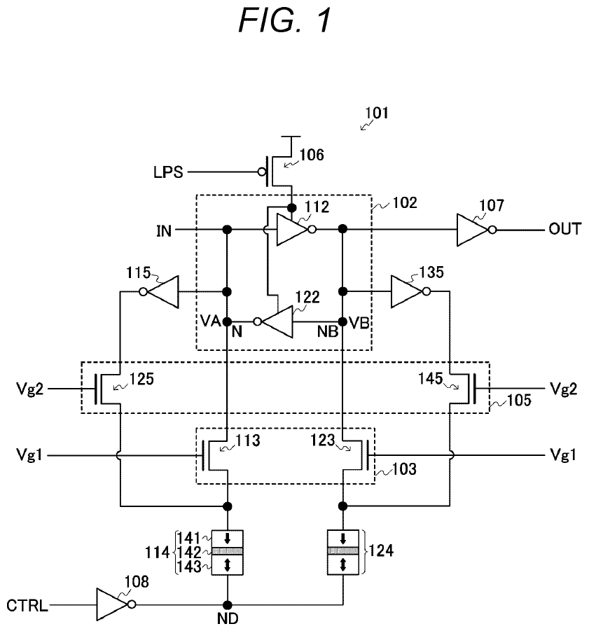

FIG. 1 is a diagram illustrating a configuration example of a storage device according to a first embodiment.

In the drawing, a storage device 101 includes a latch circuit 102, variable resistance circuits 103 and 105, voltage controlled magnetoresistive effect elements 114 and 124, inverters 107, 108, 115, and 135, and a power gating transistor 106.

Note that, the latch circuit 102 is an example of a volatile storage unit described in the claims. Each of the voltage controlled magnetoresistive effect elements 114 and 124 is an example of a nonvolatile storage unit. At this time, the nonvolatile storage unit can retain, in a nonvolatile manner, data retained in the volatile storage unit in a volatile manner. Furthermore, the nonvolatile storage unit can write the data retained in a nonvolatile manner by the nonvolatile storage unit back into the volatile storage unit. Note that, the term “volatile” as used herein means that power is required to retain data. Furthermore, the term “nonvolatile” as used herein means that power is not required to hold data.

Note that, in the present specification, processing of writing data retained in the volatile storage unit to the nonvolatile storage unit is referred to as storing, and processing of writing data retained in the nonvolatile storage unit back to the volatile storage unit is referred to as restoring.

The latch circuit 102 complementarily retains data. At this time, the latch circuit 102 operates as a bistable circuit and can retain the data in a volatile manner. The latch circuit 102 includes volatile storage nodes N and NB that complementarily retain pieces of data. Each of the volatile storage nodes N and NB retains the data in a volatile manner. At this time, the latch circuit 102 can latch input data IN, complementarily retain a logical value corresponding to the input data IN in each of the volatile storage nodes N and NB, and output the logical value as output data OUT with the inverter 107 interposed therebetween. Note that, the term “complementary” as used herein refers to a relationship in which, when data ‘0’ is retained in the volatile storage node N, data ‘1’ is retained in the volatile storage node NB, and when data ‘1’ is retained in the volatile storage node N, the data ‘0’ is retained in the volatile storage node NB.

The latch circuit 102 includes inverters 112 and 122. Each of the inverters 112 and 122 can include a complementary metal oxide semiconductor (CMOS) transistor. For example, each of the inverters 112 and 122 may include a series connection of a PMOS transistor and an NMOS transistor.

An input of the inverter 112 is connected to an output of the inverter 122, and an input of the inverter 122 is connected to an output of the inverter 112. At this time, the volatile storage node N can be provided at a connection point between the input of the inverter 112 and the output of the inverter 122, and the volatile storage node NB can be provided at a connection point between the input of the inverter 122 and the output of the inverter 112.

Each of the voltage controlled magnetoresistive effect elements 114 and 124 has a voltage controlled magnetic anisotropy (VCMA) effect. At this time, each of the voltage controlled magnetoresistive effect elements 114 and 124 can operate as a VC-MRAM (Voltage Controlled Magnetoresistive Random Access Memory). Here, a resistance state of each of the voltage controlled magnetoresistive effect elements 114 and 124 can take a low resistance state and a high resistance state. At this time, each of the voltage controlled magnetoresistive effect elements 114 and 124 can transition between the low resistance state and the high resistance state by reversing a magnetization direction on the basis of the VCMA effect.

Each of the voltage controlled magnetoresistive effect elements 114 and 124 includes a pinned layer 141, a tunnel barrier layer 142, and a free layer 143. The tunnel barrier layer 142 is sandwiched between the pinned layer 141 and the free layer 143. The pinned layer 141 of the voltage controlled magnetoresistive effect element 114 is connected to each of MOS transistors 113 and 125. The pinned layer 141 of the voltage controlled magnetoresistive effect element 124 is connected to each of MOS transistors 123 and 145. The free layer 143 of each of the voltage controlled magnetoresistive effect elements 114 and 124 is connected to a drive terminal ND.

The pinned layer 141 is a layer having magnetic anisotropy and an invariable magnetization direction. The pinned layer 141 can include, for example, CoFeB, a CoFeC alloy, an NiFeB alloy, an NiFeC alloy, or the like. Furthermore, the pinned layer 141 may have a laminated ferri-pin structure in which a plurality of ferromagnetic layers are laminated with a nonmagnetic layer interposed therebetween. Co, CoFe, CoFeB, or the like can be used as a material of the ferromagnetic layer constituting a magnetization fixed layer having the laminated ferri-pin structure. Furthermore, Ru, Re, Ir, Os, or the like can be used as a material of the nonmagnetic layer.

The pinned layer 141 can have a configuration in which an orientation of the magnetization is fixed by using an antiferromagnetic coupling between an antiferromagnetic layer and a ferromagnetic layer. Examples of a material of the antiferromagnetic layer include magnetic materials such as an FeMn alloy, a PtMn alloy, a PtCrMn alloy, an NiMn alloy, an IrMn alloy, NiO, and Fe₂O₃. Furthermore, a nonmagnetic element such as Ag, Cu, Au, Al, Si, Bi, Ta, B, C, O, N, Pd, Pt, Zr, Hf, Ir, W, Mo, or Nb can be added to these magnetic materials.

The tunnel barrier layer 142 applies an electric field to the free layer 143 to impart a voltage controlled magnetic anisotropy effect. The tunnel barrier layer 142 can include an oxide of at least one element selected from the group of Mg, Al, Ti, Si, Zn, Zr, Hf, Ta, Bi, Cr, Ga, La, Gd, Sr, and Ba, or a nitride of at least one element selected from the group of Mg, Al, Ti, Si, Zn, Zr, Hf, Ta, Bi, Cr, Ga, La, Gd, Sr, and Ba.

Furthermore, an insulator such as MgF2, CaF, SrTiO2, AlLaO3, or AINO, a dielectric, or a semiconductor may be used. Layers of these elements may be laminated. Note that, a thickness of the tunnel barrier layer 142 is suitably set to be greater than or equal to 0.6 nm.

The free layer 143 has magnetic anisotropy, and a magnetization direction of magnetism induced on the basis of a voltage can be reversed. Furthermore, the free layer 143 is a layer having the VCMA effect. A state in which the magnetization direction of the free layer 143 is the same as the magnetization direction of the pinned layer 141 and a state in which the magnetization directions are different from each other are referred to as a parallel state and an antiparallel state, respectively. Each of the voltage controlled magnetoresistive effect elements 114 and 124 is in the low resistance state in a parallel state, and is in the high resistance state in an antiparallel state. The free layer 143 can change the magnetization direction on the basis of voltage application to each of the voltage controlled magnetoresistive effect elements 114 and 124.

Furthermore, the free layer 143 can include cobalt iron (CoFe), cobalt iron boron (CoFeB), Fe, iron boride (FeB), or the like. Furthermore, the free layer 143 may contain a transition metal (Hf, Ta, VWe, Ir, Pt, Au, Zr, Nb, Mo, Ru, Rh, Pd, Ag, Ti, V, Cr, Mn, Ni, or Cu) or the like. Furthermore, the free layer 143 may contain a nitride or an oxide. Furthermore, iridium (Ir) or osmium (Os) can be used as a material that induces proximity magnetic moment induction to the magnetic materials. Note that, a heavy metal may be added to the free layer 143 to improve the VCMA effect. In order to cause each of the voltage controlled magnetoresistive effect elements 114 and 124 to have the VCMA effect, a thickness of the free layer 143 is suitably 3.0 nm or less.

Furthermore, the free layer 143 may have a laminated structure in which a plurality of ferromagnetic layers are laminated with a nonmagnetic layer interposed therebetween. At this time, two ferromagnetic layers adjacent to each other with the nonmagnetic layer interposed therebetween may be exchange-coupled. The nonmagnetic layer can include Mg, Al, Ti, Si, Zn, Zr, Hf, Ta, Bi, Cr, Ga, La, Gd, Sr, Ba, VWe, Ir, Pt, Au, Nb, Mo, Ru, Rh, Pd, Ag, V, Mn, Ni, Cu, or the like.

Formation of the pinned layer 141, tunnel barrier layer 142, and free layer 143 may be performed by a physical vapor deposition (PVD) method such as a sputtering method, an ion beam deposition method, or a vacuum deposition method, an atomic layer deposition (ALD) method, or a chemical vapor deposition (CVD) method. Furthermore, a reactive ion etching (RIE) method or an ion milling method may be used for patterning the pinned layer 141, tunnel barrier layer 142, and free layer 143.

The variable resistance circuit 103 changes a resistance such that cell voltages become substantially equal to each other between when each of the voltage controlled magnetoresistive effect elements 114 and 124 transitions from the high resistance state to the low resistance state and when each of the voltage controlled magnetoresistive effect elements transitions from the low resistance state to the high resistance state. Note that, “substantially equal to each other” includes not only a case where two things are equal to each other but also a case where there is a deviation of about several percent. The cell voltage at this time is equal to a reversal voltage. The cell voltage is a voltage applied to each of the voltage controlled magnetoresistive effect elements 114 and 124. The reversal voltage is a voltage that reverses the magnetization direction of each of the voltage controlled magnetoresistive effect elements 114 and 124 on the basis of the VCMA effect. When each of the voltage controlled magnetoresistive effect elements 114 and 124 transitions from the high resistance state to the low resistance state and when the voltage controlled magnetoresistive effect element transitions from the low resistance state to the high resistance state, the reversal voltages are substantially equal to each other. When the reversal voltage is applied to each of the voltage controlled magnetoresistive effect elements 114 and 124, perpendicular magnetic anisotropy of each of the voltage controlled magnetoresistive effect elements 114 and 124 becomes 0. The variable resistance circuit 103 is arranged between each of the voltage controlled magnetoresistive effect elements 114 and 124 and the latch circuit 102.

The variable resistance circuit 103 includes the MOS transistors 113 and 123. An on-resistance of each of the MOS transistors 113 and 123 changes on the basis of a gate voltage Vg1. The MOS transistor 113 is connected between the voltage controlled magnetoresistive effect element 114 and the volatile storage node N. The MOS transistor 123 is connected between the voltage controlled magnetoresistive effect element 124 and the volatile storage node NB. At this time, the MOS transistor 113 can be used not only as a variable resistance element but also as a storing transistor that stores data from the latch circuit 102 to the voltage controlled magnetoresistive effect element 114 and a restoring transistor that restores the data from the voltage controlled magnetoresistive effect element 114 to the latch circuit 102. Furthermore, the MOS transistor 123 can be used not only as a variable resistance element but also as a storing transistor that stores data from the latch circuit 102 to the voltage controlled magnetoresistive effect element 124 and a restoring transistor that restores the data from the voltage controlled magnetoresistive effect element 124 to the latch circuit 102. Note that, the MOS transistors 113 and 123 are examples of variable resistance elements described in the claims.

The variable resistance circuit 105 changes a resistance such that the cell voltages become substantially equal to each other between when each of the voltage controlled magnetoresistive effect elements 114 and 124 transitions from the high resistance state to the low resistance state and when each of the voltage controlled magnetoresistive effect elements transitions from the low resistance state to the high resistance state. The cell voltage at this time is equal to a reversal voltage. The variable resistance circuit 105 is arranged between each of the voltage controlled magnetoresistive effect elements 114 and 124 and the latch circuit 102 with the inverters 115 and 135 interposed therebetween, respectively.

The variable resistance circuit 105 includes the MOS transistors 125 and 145. An on-resistance of each of the MOS transistors 125 and 145 changes on the basis of a gate voltage Vg2. The MOS transistor 125 is connected between the voltage controlled magnetoresistive effect element 114 and the volatile storage node N with the inverter 115 interposed therebetween. At this time, the MOS transistor 125 and the inverter 115 are connected in series to each other. A series circuit of the MOS transistor 125 and the inverter 115 is connected in parallel to the MOS transistor 113. The MOS transistor 145 is connected between the voltage controlled magnetoresistive effect element 124 and the volatile storage node NB with the inverter 135 interposed therebetween. At this time, the MOS transistor 145 and the inverter 135 are connected in series to each other. A series circuit of the MOS transistor 145 and the inverter 135 is connected in parallel to the MOS transistor 113. Note that, the MOS transistors 125 and 145 are examples of variable resistance elements described in the claims.

The power gating transistor 106 performs power gating of each of the inverters 112 and 122. At this time, the power gating transistor 106 can extract electric charges accumulated in the volatile storage nodes N and NB to a power supply potential. Opening and closing of the power gating transistor 106 is controlled on the basis of a power gating signal LPS. The power gating transistor 106 may be a PMOS transistor. At this time, the power gating signal LPS is applied to a gate of the power gating transistor 106.

A drive voltage for driving each of the voltage controlled magnetoresistive effect elements 114 and 124 is applied to the drive terminal ND. The drive voltage can be generated by reversing a control voltage CTRL input to the inverter 108.

Here, in a case where the voltage controlled magnetoresistive effect element 114 is written with a high resistance on the basis of the gate voltage Vg1, the voltage controlled magnetoresistive effect element 124 is written with a low resistance on the basis of the gate voltage Vg2.

At this time, in a case where the voltage controlled magnetoresistive effect element 114 is in the low resistance state when high-resistance writing is performed, the reversal voltage is applied to the voltage controlled magnetoresistive effect element 114 on the basis of the gate voltage Vg1. On the other hand, in a case where the voltage controlled magnetoresistive effect element 114 is in the high resistance state when high-resistance writing is performed, a voltage higher than the reversal voltage is applied to the voltage controlled magnetoresistive effect element 114 on the basis of the gate voltage Vg1.

Furthermore, in a case where the voltage controlled magnetoresistive effect element 124 is in the high resistance state when low-resistance writing is performed, the reversal voltage is applied to the voltage controlled magnetoresistive effect element 124 on the basis of the gate voltage Vg2. On the other hand, in a case where the voltage controlled magnetoresistive effect element 124 is in the low resistance state when low-resistance writing is performed, a voltage lower than the reversal voltage is applied to the voltage controlled magnetoresistive effect element 124 on the basis of the gate voltage Vg2.

In a case where the voltage controlled magnetoresistive effect element 114 is written with a low resistance on the basis of the gate voltage Vg1, the voltage controlled magnetoresistive effect element 124 is written with high resistance on the basis of the gate voltage Vg2.

At this time, in a case where the voltage controlled magnetoresistive effect element 114 is in the high resistance state when low-resistance writing is performed, the reversal voltage is applied to the voltage controlled magnetoresistive effect element 114 on the basis of the gate voltage Vg1. On the other hand, in a case where the voltage controlled magnetoresistive effect element 114 is in the low resistance state when low-resistance writing is performed, a voltage lower than the reversal voltage is applied to the voltage controlled magnetoresistive effect element 114 on the basis of the gate voltage Vg1.

Furthermore, in a case where the voltage controlled magnetoresistive effect element 124 is in the low resistance state when high-resistance writing is performed, the reversal voltage is applied to the voltage controlled magnetoresistive effect element 124 on the basis of the gate voltage Vg2. On the other hand, in a case where the voltage controlled magnetoresistive effect element 124 is in the high resistance state when high-resistance writing is performed, a voltage higher than the reversal voltage is applied to the voltage controlled magnetoresistive effect element 124 on the basis of the gate voltage Vg2.

Then, it is assumed that data is complementarily stored from the latch circuit 102 to each of the voltage controlled magnetoresistive effect elements 114 and 124. At this time, a first storing operation in which the variable resistance circuit 103 is interposed between the latch circuit 102 and each of the voltage controlled magnetoresistive effect elements 114 and 124 and a second storing operation in which the variable resistance circuit 105 is interposed between the latch circuit 102 and each of the voltage controlled magnetoresistive effect elements 114 and 124 are performed. Furthermore, the drive terminal ND is driven such that voltages in the same direction are applied to the voltage controlled magnetoresistive effect elements 114 and 124. Note that, the second storing operation may be performed after the first storing operation is performed, or the first storing operation may be performed after the second storing operation is performed.

In the first storing operation, the drive terminal ND is driven such that the reversal voltage is applied to one of the voltage controlled magnetoresistive effect elements 114 and 124 when the gate voltage Vg1 is applied to each of the MOS transistors 113 and 123. At this time, the voltage lower than the reversal voltage is applied to the other of the voltage controlled magnetoresistive effect elements 114 and 124.

In the second storing operation, the drive terminal ND is driven such that the reversal voltage is applied to the other of the voltage controlled magnetoresistive effect elements 114 and 124 when the gate voltage Vg2 is applied to each of the MOS transistors 125 and 145. At this time, the voltage lower than the reversal voltage is applied to one of the voltage controlled magnetoresistive effect elements 114 and 124.

It is assumed that the data is complementarily restored from each of the voltage controlled magnetoresistive effect elements 114 and 124 to the latch circuit 102. At this time, the drive terminal ND is driven such that a voltage lower than the voltage applied to the pinned layer 141 is applied to the free layer 143.

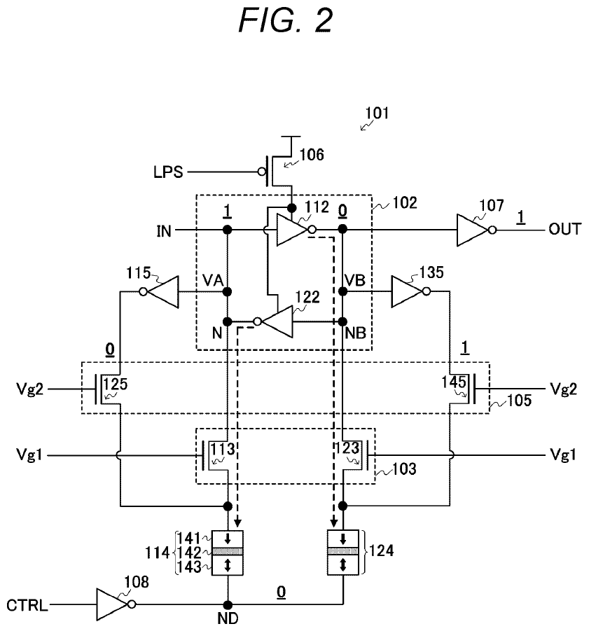

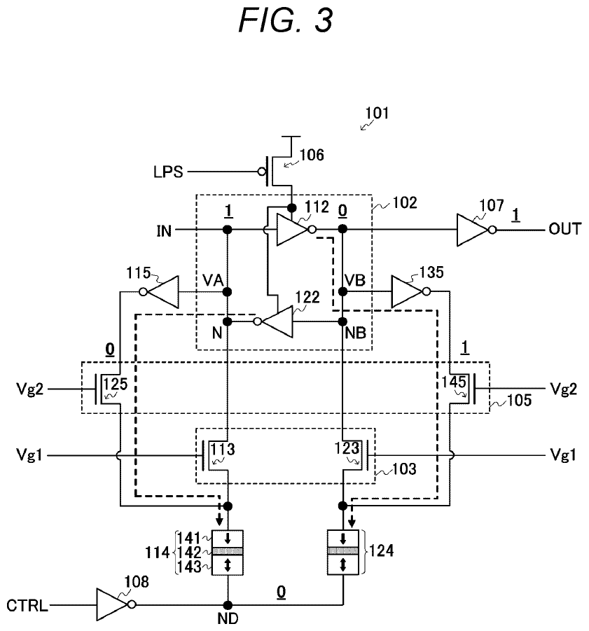

FIG. 2 is a diagram illustrating a first example of the first storing operation of the storage device according to the first embodiment, and FIG. 3 is a diagram illustrating a first example of the second storing operation of the storage device according to the first embodiment. Note that, in the first examples of the first storing operation and the second storing operation, a case where a logical value ‘1’ is retained in the volatile storage node N and a logical value ‘0’ is retained in the volatile storage node NB, and, at that time, a node voltage VA is 1 V and a node voltage VB is 0 V will be taken.

Furthermore, as an example, a case where a logical value ‘0’ is set to the drive terminal ND and a drive voltage at that time is 0 V will be taken. Note that, the node voltages VA and VB and the drive voltage are not limited to these values.

In FIG. 2, in the first storing operation, a voltage of 1 V is applied between the volatile storage node N and the drive terminal ND, and a voltage of 0 V is applied between the volatile storage node NB and the drive terminal ND. Here, a voltage between the volatile storage node N and the drive terminal ND is divided into a voltage applied to the on-resistance of the MOS transistor 113 and the cell voltage applied to the voltage controlled magnetoresistive effect element 114. At this time, the gate voltage Vg1 is set such that when the voltage between the volatile storage node N and the drive terminal ND is divided by the on-resistance of the MOS transistor 113, the cell voltage applied to the voltage controlled magnetoresistive effect element 114 in the low resistance state matches the reversal voltage. The gate voltage Vg2 is set such that the MOS transistors 125 and 145 are turned off.

Here, in a case where the voltage controlled magnetoresistive effect element 114 is in the low resistance state at the time of high-resistance writing, since the reversal voltage is applied to the voltage controlled magnetoresistive effect element 114, the voltage controlled magnetoresistive effect element 114 transitions from the low resistance state to the high resistance state. On the other hand, in a case where the voltage controlled magnetoresistive effect element 114 is in the high resistance state at the time of high-resistance writing, a voltage division ratio of the MOS transistor 113 to the on-resistance decreases as compared with a case where the voltage controlled magnetoresistive effect element 114 is in the low resistance state. Thus, the cell voltage applied to the voltage controlled magnetoresistive effect element 114 becomes higher than the reversal voltage, and an in-plane rotational component appears due to the in-plane magnetic anisotropy of the voltage controlled magnetoresistive effect element 114, but this rotational component does not contribute to the inversion of the magnetization direction, such that the high resistance state of the voltage controlled magnetoresistive effect element 114 is maintained.

On the other hand, the voltage of 0 V is applied between the volatile storage node NB and the drive terminal ND, and the cell voltage of the voltage controlled magnetoresistive effect element 124 is 0 V. Thus, the magnetization direction of the voltage controlled magnetoresistive effect element 124 does not change, and writing is not performed on the voltage controlled magnetoresistive effect element 124.

In FIG. 3, in the second storing operation, a voltage of 1 V is also applied between the volatile storage node N and the drive terminal ND, and a voltage of 0 V is also applied between the volatile storage node NB and the drive terminal ND. On the other hand, a voltage of 0 V is applied between an output of the inverter 115 and the drive terminal ND, and a voltage of 1 V is applied between an output of the inverter 135 and the drive terminal ND. Here, a voltage between the output of the inverter 135 and the drive terminal ND is divided into a voltage applied to the on-resistance of the MOS transistor 145 and the cell voltage applied to the voltage controlled magnetoresistive effect element 124. At this time, the gate voltage Vg2 is set such that when a voltage between the volatile storage node NB and the drive terminal ND is divided by the on-resistance of the MOS transistor 145, the cell voltage applied to the voltage controlled magnetoresistive effect element 124 in the high resistance state matches the reversal voltage. The gate voltage Vg1 is set such that the MOS transistors 113 and 123 are turned off.

Here, in a case where the voltage controlled magnetoresistive effect element 124 is in the high resistance state at the time of low-resistance writing, since the reversal voltage is applied to the voltage controlled magnetoresistive effect element 124, the voltage controlled magnetoresistive effect element 124 transitions from the high resistance state to the low resistance state. On the other hand, in a case where the voltage controlled magnetoresistive effect element 124 is in the low resistance state at the time of low-resistance writing, a voltage division ratio of the MOS transistor 145 to the on-resistance increases as compared with a case where the voltage controlled magnetoresistive effect element 124 is in the high resistance state. Thus, the cell voltage applied to the voltage controlled magnetoresistive effect element 124 becomes lower than the reversal voltage, and the low resistance state of the voltage controlled magnetoresistive effect element 124 is maintained by the perpendicular magnetic anisotropy of the voltage controlled magnetoresistive effect element 124.

On the other hand, a voltage of 0 V is applied between the output of the inverter 115 and the drive terminal ND, and the cell voltage of the voltage controlled magnetoresistive effect element 114 becomes 0 V. Thus, the magnetization direction of the voltage controlled magnetoresistive effect element 114 does not change, and the high resistance state of the voltage controlled magnetoresistive effect element 114 is maintained.

As described above, in the first example of the storing operation, in the high-resistance writing of the voltage controlled magnetoresistive effect element 114, the voltage is applied to the voltage controlled magnetoresistive effect element 114 with the MOS transistor 113 between the volatile storage node N and the drive terminal ND interposed therebetween. On the other hand, in the low-resistance writing of the voltage controlled magnetoresistive effect element 124, the voltage is applied to the voltage controlled magnetoresistive effect element 124 with the inverter 135 and the MOS transistor 145 between the volatile storage node NB and the drive terminal ND interposed therebetween.

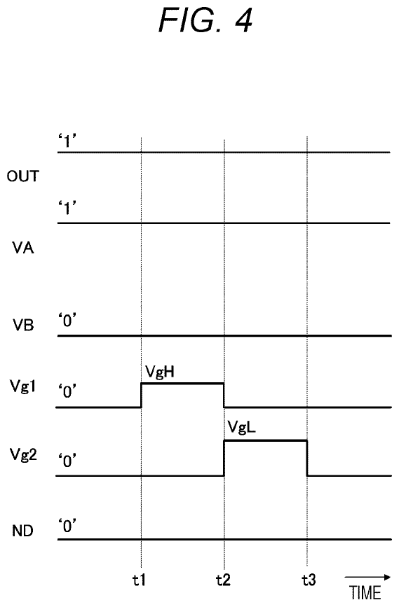

FIG. 4 is a timing chart illustrating a first example of a storing timing of the storage device according to the first embodiment. Note that, in the drawing, an example in which the second storing operation is performed after the first storing operation is performed is illustrated, but the first storing operation may be performed after the second storing operation is performed.

In the drawing, it is assumed that a logical value ‘1’ is retained in the volatile storage node N and a logical value ‘0’ is retained in the volatile storage node NB. At this time, the node voltage VA is set to 1 V, the node voltage VB is set to 0 V, and the output data OUT is set to a logical value ‘1’. Furthermore, the drive terminal ND is set to 0 V.

Next, the gate voltage Vg1 is set to VgH (t1). VgH is a voltage applied to gates of the MOS transistors 113 and 123 when the voltage controlled magnetoresistive effect elements 114 and 124 are written with a high resistance. At this time, the first storing operation is performed, and the voltage controlled magnetoresistive effect element 114 is set to the high resistance state.

Next, after the gate voltage Vg1 is set to 0 V, the gate voltage Vg2 is set to VgL (t2). VgL is a voltage applied to gates of the MOS transistors 113 and 123 when the voltage controlled magnetoresistive effect elements 114 and 124 are written with a low resistance. Note that, VgL is set to a voltage higher than VgH. At this time, the second storing operation is performed, and the voltage controlled magnetoresistive effect element 124 is set to the low resistance state.

Next, the gate voltage Vg2 is set to 0 V (t3), and the storing of the forward logic from the latch circuit 102 to each of the voltage controlled magnetoresistive effect elements 114 and 124 is completed.

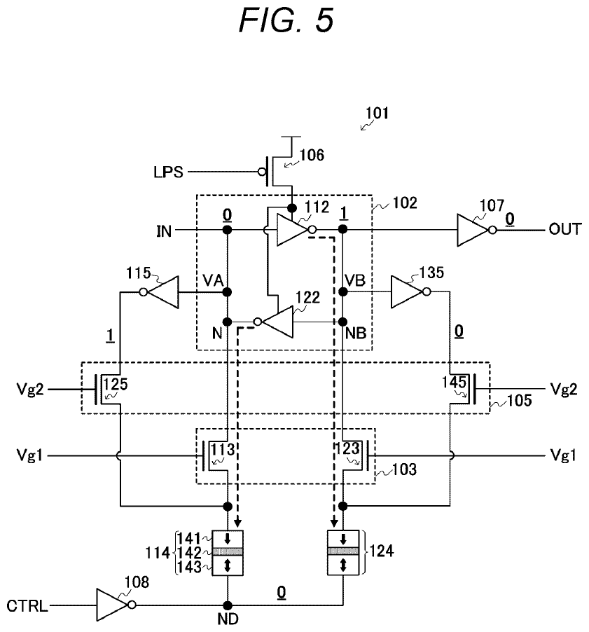

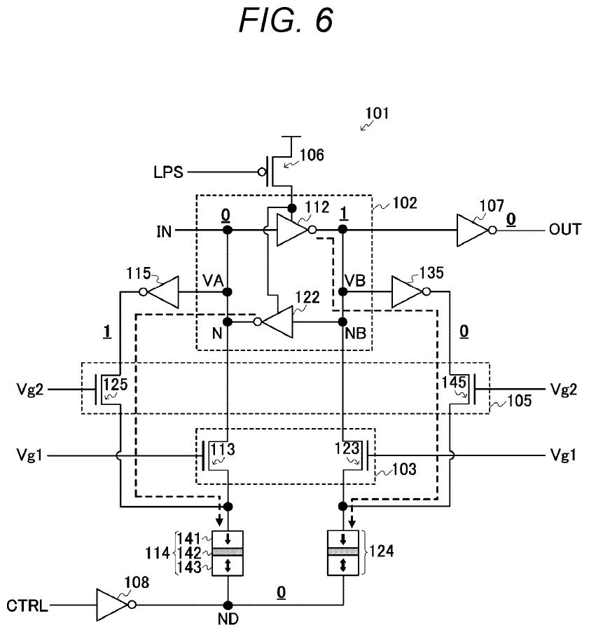

FIG. 5 is a diagram illustrating a second example of the first storing operation of the storage device according to the first embodiment, and FIG. 6 is a diagram illustrating a second example of the second storing operation of the storage device according to the first embodiment. Note that, in the second examples of the first storing operation and the second storing operation, as an example, the case where a logical value ‘0’ is retained in the volatile storage node N and a logical value ‘1’ is retained in the volatile storage node NB has been taken.

In FIG. 5, in the first storing operation, a voltage of 0 V is applied between the volatile storage node N and the drive terminal ND, and a voltage of 1 V is applied between the volatile storage node NB and the drive terminal ND. Here, the voltage between the volatile storage node NB and the drive terminal ND is divided into a voltage applied to the on-resistance of the MOS transistor 123 and the cell voltage applied to the voltage controlled magnetoresistive effect element 124. The gate voltage Vg1 is set such that when the voltage between the volatile storage node NB and the drive terminal ND is divided by the on-resistance of the MOS transistor 123, the cell voltage applied to the voltage controlled magnetoresistive effect element 124 in the low resistance state matches the reversal voltage. The gate voltage Vg2 is set such that the MOS transistors 125 and 145 are turned off.

Here, in a case where the voltage controlled magnetoresistive effect element 124 is in the low resistance state at the time of high-resistance writing, since the reversal voltage is applied to the voltage controlled magnetoresistive effect element 124, the voltage controlled magnetoresistive effect element 124 transitions from the low resistance state to the high resistance state. On the other hand, in a case where the voltage controlled magnetoresistive effect element 124 is in the high resistance state at the time of high-resistance writing, a voltage division ratio to the on-resistance of the MOS transistor 123 decreases as compared with a case where the voltage controlled magnetoresistive effect element 124 is in the low resistance state. Thus, the cell voltage applied to the voltage controlled magnetoresistive effect element 124 is higher than the reversal voltage, and an in-plane rotational component appears due to in-plane magnetic anisotropy of the voltage controlled magnetoresistive effect element 124, but the rotational component does not contribute to reversal of the magnetization direction, such that the high resistance state of the voltage controlled magnetoresistive effect element 124 is maintained.

On the other hand, the voltage of 0 V is applied between the volatile storage node N and the drive terminal ND, and the cell voltage of the voltage controlled magnetoresistive effect element 114 is 0 V. Thus, the magnetization direction of the voltage controlled magnetoresistive effect element 114 does not change, and writing is not performed on the voltage controlled magnetoresistive effect element 114.

In FIG. 6, in the second storing operation, a voltage of 0 V is also applied between the volatile storage node N and the drive terminal ND, and a voltage of 1 V is also applied between the volatile storage node NB and the drive terminal ND. On the other hand, a voltage of 1 V is applied between the output of the inverter 115 and the drive terminal ND, and a voltage of 0 V is applied between the output of the inverter 135 and the drive terminal ND. Here, a voltage between the output of the inverter 115 and the drive terminal ND is divided into a voltage applied to the on-resistance of the MOS transistor 125 and the cell voltage applied to the voltage controlled magnetoresistive effect element 114. At this time, the gate voltage Vg2 is set such that when the voltage between the volatile storage node N and the drive terminal ND is divided by the on-resistance of the MOS transistor 125, the cell voltage applied to the voltage controlled magnetoresistive effect element 114 in the high resistance state matches the reversal voltage. The gate voltage Vg1 is set such that the MOS transistors 113 and 123 are turned off.

### Here, in a Case Where the Voltage Controlled

magnetoresistive effect element 114 is in the high resistance state at the time of low-resistance writing, since the reversal voltage is applied to the voltage controlled magnetoresistive effect element 114, the voltage controlled magnetoresistive effect element 114 transitions from the high resistance state to the low resistance state. On the other hand, when the voltage controlled magnetoresistive effect element 114 is in the low resistance state at the time of low-resistance writing, a voltage division ratio of the MOS transistor 125 to the on-resistance increases as compared with a case where the voltage controlled magnetoresistive effect element 114 is in the high resistance state. Thus, the cell voltage applied to the voltage controlled magnetoresistive effect element 114 is lower than the reversal voltage, and the low resistance state of the voltage controlled magnetoresistive effect element 114 is maintained due to the perpendicular magnetic anisotropy of the voltage controlled magnetoresistive effect element 114.

On the other hand, a voltage of 0 V is applied between the output of the inverter 135 and the drive terminal ND, and the cell voltage of the voltage controlled magnetoresistive effect element 124 becomes 0 V. Thus, the magnetization direction of the voltage controlled magnetoresistive effect element 124 does not change, and the high resistance state of the voltage controlled magnetoresistive effect element 124 is maintained.

As described above, in the second example of the storing operation, in the high-resistance writing of the voltage controlled magnetoresistive effect element 124, the voltage is applied to the voltage controlled magnetoresistive effect element 124 with the MOS transistor 123 between the volatile storage node NB and the drive terminal ND interposed therebetween. On the other hand, in the low-resistance writing of the voltage controlled magnetoresistive effect element 114, the voltage is applied to the voltage controlled magnetoresistive effect element 114 with the inverter 115 and the MOS transistor 125 between the volatile storage node N and the drive terminal ND interposed therebetween.

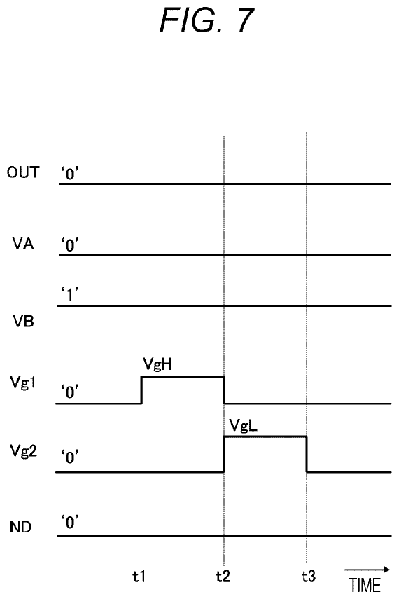

FIG. 7 is a timing chart illustrating a second example of the storing timing of the storage device according to the first embodiment. Note that, in the drawing, an example in which the second storing operation is performed after the first storing operation is performed is illustrated, but the first storing operation may be performed after the second storing operation is performed.

In the drawing, it is assumed that a logical value ‘0’ is retained in the volatile storage node N and a logical value ‘1’ is retained in the volatile storage node NB. At this time, the node voltage VA is set to 0 V, the node voltage VB is set to 1 V, and the output data OUT is set to a logical value ‘0’. Furthermore, the drive terminal ND is set to 0 V.

Next, the gate voltage Vg1 is set to VgH (t1). At this time, the first storing operation is performed, and the voltage controlled magnetoresistive effect element 124 is set to the high resistance state.

Next, the gate voltage Vg1 is set to 0 V, and the gate voltage Vg2 is set to VgL (t2). At this time, the second storing operation is performed, and the voltage controlled magnetoresistive effect element 114 is set to the low resistance state.

Next, the gate voltage Vg2 is set to 0 V (t3), and the storing of the forward logic from the latch circuit 102 to each of the voltage controlled magnetoresistive effect elements 114 and 124 is completed.

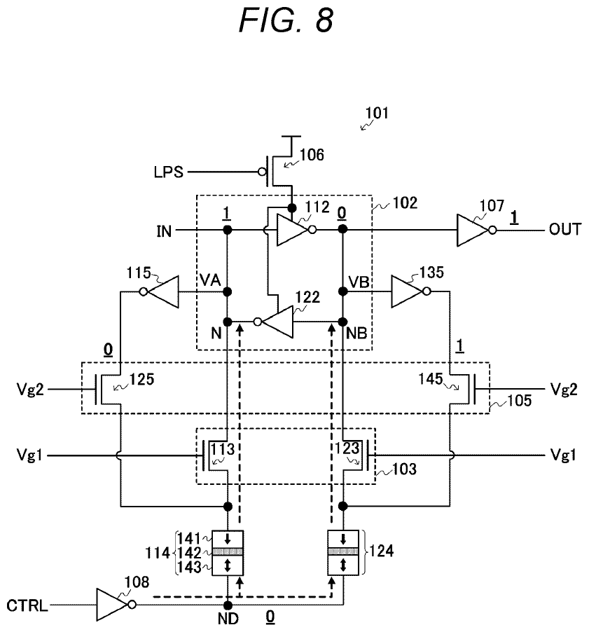

FIG. 8 is a diagram illustrating an example of the restoring operation of the storage device according to the first embodiment.

In the drawing, in the restoring operation, the gate voltage Vg1 is set to VgH, and the drive terminal ND is driven such that the voltage lower than the voltage applied to the pinned layer 141 is applied to the free layer 143. The voltage applied to the drive terminal ND may be 0 V. Furthermore, the gate voltage Vg2 is set such that the MOS transistors 125 and 145 are turned off. Here, it is assumed that the voltage controlled magnetoresistive effect element 114 is in the high resistance state and the voltage controlled magnetoresistive effect element 124 is in the low resistance state. Then, when the gate voltage Vg1 is set to VgH, the power gating transistor 106 is turned off, and the electric charge accumulated in the latch circuit 102 is discharged. Then, when the power gating transistor 106 is turned on, the node voltage VA is higher than the node voltage VB, and a logical value ‘1’ is restored in the volatile storage node N and a logical value ‘0’ is restored in the volatile storage node NB.

Here, when a logical value ‘1’ is restored in the volatile storage node N, the node voltage VA becomes 1 V, and the voltage is applied to the voltage controlled magnetoresistive effect element 114. At this time, the gate voltage Vg1 is set to VgH, and when the voltage controlled magnetoresistive effect element 114 is in the high resistance state, the high resistance state of the voltage controlled magnetoresistive effect element 114 is maintained as it is. On the other hand, when a logical value ‘0’ is restored in the volatile storage node NB, the node voltage VB becomes 0 V, and since the voltage is not applied to the voltage controlled magnetoresistive effect element 124, the low resistance state of the voltage controlled magnetoresistive effect element 124 is maintained as it is.

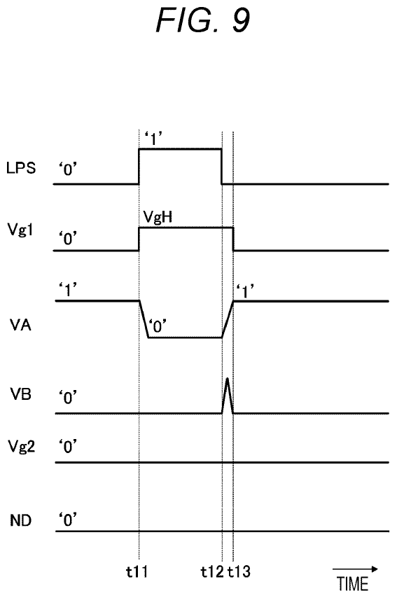

FIG. 9 is a timing chart illustrating an example of the restoring timing of the storage device according to the first embodiment.

In the drawing, it is assumed that the voltage controlled magnetoresistive effect element 114 holds the high resistance state, and the voltage controlled magnetoresistive effect element 124 holds the low resistance state.

Here, at the time of restoring, the gate voltage Vg1 is set to VgH, the gate voltage Vg2 is set to 0 V, and 0 V is applied to the drive terminal ND (t11). Furthermore, the power gating signal LPS rises, the power gating transistor 106 is turned off, and the electric charge accumulated in the latch circuit 102 is discharged.

Next, the power gating signal LPS falls, and the power gating transistor 106 is turned on (t12). At this time, the node voltage VA is higher than the node voltage VB, and a logical value ‘1’ is restored in the volatile storage node N and a logical value ‘0’ is restored in the volatile storage node NB.

Next, the gate voltage Vg1 is set to 0 V (t13). At this time, the voltage controlled magnetoresistive effect elements 114 and 124 are disconnected from the latch circuit 102. Furthermore, the voltage controlled magnetoresistive effect element 114 maintains the high resistance state, and the voltage controlled magnetoresistive effect element 124 maintains the low resistance state.

As described above, in the above-described first embodiment, the voltage controlled magnetoresistive effect elements 114 and 124 are provided in the latch circuit 102. Therefore, the data retained in the latch circuit 102 can be stored in the voltage controlled magnetoresistive effect elements 114 and 124 on the basis of voltage drive. Thus, a nonvolatile storage function can be added to the latch circuit 102 while suppressing an increase in power consumption when the data retained in the latch circuit 102 is stored in the voltage controlled magnetoresistive effect elements 114 and 124.

Furthermore, the MOS transistors 113 and 123 are connected between the latch circuit 102 and the voltage controlled magnetoresistive effect elements 114 and 124, and the MOS transistors 125 and 145 are connected with the inverters 115 and 135 interposed therebetween, respectively. Therefore, the data can be written to each of the voltage controlled magnetoresistive effect elements 114 and 124 on the basis of the cell voltage having the same polarity applied to each of the voltage controlled magnetoresistive effect elements 114 and 124 while corresponding to the data complementarily retained in the latch circuit 102.

At this time, each of the MOS transistors 113 and 123 can change a resistance such that the cell voltages become substantially equal to each other between when each of the voltage controlled magnetoresistive effect elements 114 and 124 transitions from the high resistance state to the low resistance state and when the voltage controlled magnetoresistive effect element transitions from the low resistance state to the high resistance state. Furthermore, each of the MOS transistors 125 and 145 can change resistance such that the cell voltages become substantially equal to each other between when each of the voltage controlled magnetoresistive effect elements 114 and 124 transitions from the high resistance state to the low resistance state and when the voltage controlled magnetoresistive effect element transitions from the low resistance state to the high resistance state. Therefore, each of the voltage controlled magnetoresistive effect elements 114 and 124 can transition from the high resistance state to the low resistance state while maintaining the low resistance state at the time of low-resistance writing, and can transition from the low resistance state to the high resistance state while maintaining the high resistance state at the time of high-resistance writing.

Furthermore, when data is restored from each of the voltage controlled magnetoresistive effect elements 114 and 124 to the latch circuit 102, the voltage lower than the voltage applied to the pinned layer 141 of each of the voltage controlled magnetoresistive effect elements 114 and 124 is applied to the free layer 143. Therefore, the data can be restored from each of the voltage controlled magnetoresistive effect elements 114 and 124 to the latch circuit 102 without destroying the data retained in each of the voltage controlled magnetoresistive effect elements 114 and 124.

### 2. Second Embodiment

In the above-described first embodiment, the voltage controlled magnetoresistive effect elements 114 and 124 are provided in the latch circuit 102, the drive voltage is applied to the free layer 143 of each of the voltage controlled magnetoresistive effect elements 114 and 124, and the forward logic of the latch circuit 102 is stored. In a second embodiment, the voltage controlled magnetoresistive effect elements 114 and 124 are provided in the latch circuit 102, the drive voltage is applied to the free layer 143 of each of the voltage controlled magnetoresistive effect elements 114 and 124, and the reverse logic of the latch circuit 102 is stored.

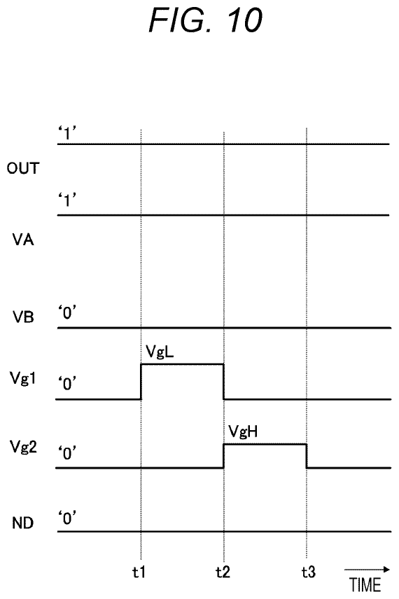

FIG. 10 is a timing chart illustrating a first example of a storing timing of a storage device according to the second embodiment. Note that, in the drawing, an example in which the second storing operation is performed after the first storing operation is performed is illustrated, but the first storing operation may be performed after the second storing operation is performed.

In the drawing, a configuration of the storage device of the second embodiment is similar to the configuration of the storage device 101 of the above-described first embodiment.

Here, it is assumed that a logical value ‘1’ is retained in the volatile storage node N and a logical value ‘0’ is retained in the volatile storage node NB. At this time, the node voltage VA is set to 1 V, the node voltage VB is set to 0 V, and the output data OUT is set to a logical value ‘1’. Furthermore, the drive terminal ND is set to 0 V.

Next, the gate voltage Vg1 is set to VgL (t1). At this time, the first storing operation is performed, and the voltage controlled magnetoresistive effect element 114 is set to the low resistance state.

Next, after the gate voltage Vg1 is set to 0 V, the gate voltage Vg2 is set to VgH (t2). At this time, the second storing operation is performed, and the voltage controlled magnetoresistive effect element 124 is set to the high resistance state.

Next, the gate voltage Vg2 is set to 0 V (t3), and the storing of the reverse logic from the latch circuit 102 to each of the voltage controlled magnetoresistive effect elements 114 and 124 is completed.

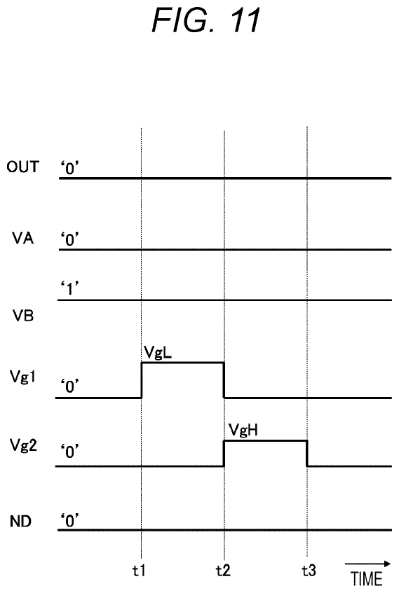

FIG. 11 is a timing chart illustrating a second example of the storing timing of the storage device according to the second embodiment. Note that, in the drawing, an example in which the second storing operation is performed after the first storing operation is performed is illustrated, but the first storing operation may be performed after the second storing operation is performed.

In the drawing, it is assumed that a logical value ‘0’ is retained in the volatile storage node N and a logical value ‘1’ is retained in the volatile storage node NB. At this time, the node voltage VA is set to 0 V, the node voltage VB is set to 1 V, and the output data OUT is set to a logical value ‘0’. Furthermore, the drive terminal ND is set to 0 V.

Next, the gate voltage Vg1 is set to VgL (t1). At this time, the first storing operation is performed, and the voltage controlled magnetoresistive effect element 124 is set to the low resistance state.

Next, after the gate voltage Vg1 is set to 0 V, the gate voltage Vg2 is set to VgH (t2). At this time, the second storing operation is performed, and the voltage controlled magnetoresistive effect element 114 is set to the high resistance state.

Next, the gate voltage Vg2 is set to 0 V (t3), and the storing of the reverse logic from the latch circuit 102 to each of the voltage controlled magnetoresistive effect elements 114 and 124 is completed.

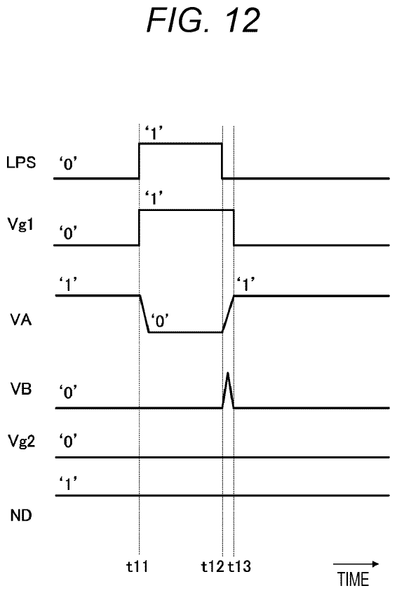

FIG. 12 is a timing chart illustrating an example of a restoring timing of the storage device according to the second embodiment. Note that, in the drawing, an example in which the voltage controlled magnetoresistive effect element 114 is set to the high resistance state and the voltage controlled magnetoresistive effect element 124 is set to the low resistance state is illustrated.

In the drawing, it is assumed that the voltage controlled magnetoresistive effect element 114 holds the low resistance state and the voltage controlled magnetoresistive effect element 124 holds the high resistance state.

Here, at the time of restoring, the gate voltage Vg1 is set such that the MOS transistors 113 and 123 are turned on, the gate voltage Vg2 is set to 0 V, and 1 V is applied to the drive terminal ND (t11). Furthermore, the power gating signal LPS rises, the power gating transistor 106 is turned off, and the electric charge accumulated in the latch circuit 102 is discharged.

Next, the power gating signal LPS falls, and the power gating transistor 106 is turned on (t12). At this time, the node voltage VA is higher than the node voltage VB, and a logical value ‘1’ is restored in the volatile storage node N and a logical value ‘0’ is restored in the volatile storage node NB.

Next, the gate voltage Vg1 is set to 0 V (t13). At this time, the voltage controlled magnetoresistive effect elements 114 and 124 are disconnected from the latch circuit 102.

Furthermore, the voltage controlled magnetoresistive effect element 114 maintains the low resistance state, and the voltage controlled magnetoresistive effect element 124 maintains the high resistance state.

As described above, in the above-described second embodiment, the reverse logic of the latch circuit 102 is stored in the voltage controlled magnetoresistive effect elements 114 and 124. Then, in a case where data is restored from each of the voltage controlled magnetoresistive effect elements 114 and 124 to the latch circuit 102, the voltage higher than the voltage applied to the pinned layer 141 of each of the voltage controlled magnetoresistive effect elements 114 and 124 is applied to the free layer 143. Therefore, a voltage can be applied such that the perpendicular magnetic anisotropy of each of the voltage controlled magnetoresistive effect elements 114 and 124 increases at the time of restoring. Thus, data can be restored from each of the voltage controlled magnetoresistive effect elements 114 and 124 to the latch circuit 102 without destroying the data retained in each of the voltage controlled magnetoresistive effect elements 114 and 124.

### 3. Third Embodiment

In the above-described first embodiment, the voltage controlled magnetoresistive effect elements 114 and 124 are provided in the latch circuit 102, the drive voltage is applied to the free layer 143 of each of the voltage controlled magnetoresistive effect elements 114 and 124, and the forward logic of the latch circuit 102 is stored. In a third embodiment, the voltage controlled magnetoresistive effect elements 114 and 124 are provided in the latch circuit 102, the drive voltage is applied to the pinned layer 141 of each of the voltage controlled magnetoresistive effect elements 114 and 124, and the forward logic of the latch circuit 102 is stored.

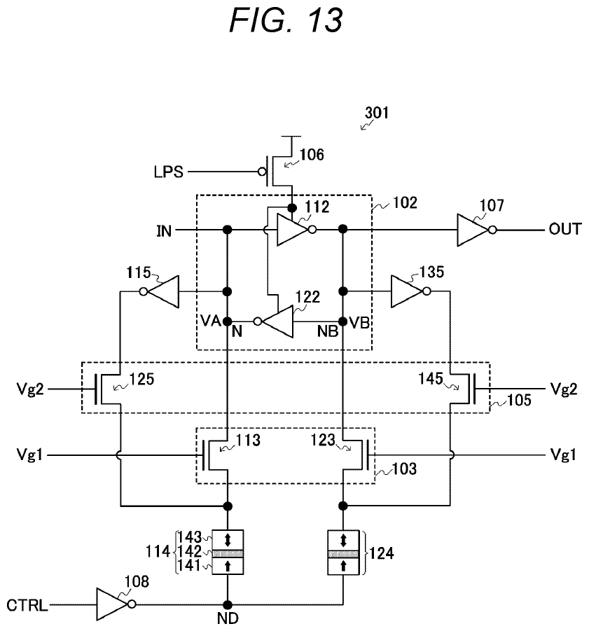

FIG. 13 is a diagram illustrating a configuration example of a storage device according to the third embodiment.

In the drawing, in a storage device 301, the connection direction of the voltage controlled magnetoresistive effect elements 114 and 124 of the above-described first embodiment is reversed. Other configurations of the storage device 301 of the third embodiment are similar to those of the storage device 101 of the above-described first embodiment.

In the voltage controlled magnetoresistive effect elements 114 and 124, the pinned layer 141 is connected to the drive terminal ND. Furthermore, the free layer 143 of the voltage controlled magnetoresistive effect element 114 is connected to each of the MOS transistors 113 and 125, and the free layer 143 of the voltage controlled magnetoresistive effect element 124 is connected to each of the MOS transistors 123 and 145.

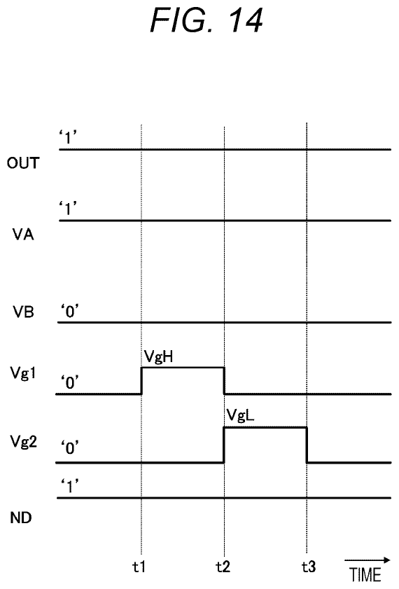

FIG. 14 is a timing chart illustrating a first example of a storing timing of the storage device according to the third embodiment. Note that, in the drawing, an example in which the second storing operation is performed after the first storing operation is performed is illustrated, but the first storing operation may be performed after the second storing operation is performed.

In the drawing, it is assumed that a logical value ‘1’ is retained in the volatile storage node N and a logical value ‘0’ is retained in the volatile storage node NB. At this time, the node voltage VA is set to 1 V, the node voltage VB is set to 0 V, and the output data OUT is set to a logical value ‘1’. Furthermore, the drive terminal ND is set to 1 V.

Next, the gate voltage Vg1 is set to VgH (t1). At this time, the first storing operation is performed, and the voltage controlled magnetoresistive effect element 114 is set to the high resistance state.

Next, after the gate voltage Vg1 is set to 0 V, the gate voltage Vg2 is set to VgL (t2). At this time, the second storing operation is performed, and the voltage controlled magnetoresistive effect element 124 is set to the low resistance state.

Next, the gate voltage Vg2 is set to 0 V (t3), and the storing of the forward logic from the latch circuit 102 to each of the voltage controlled magnetoresistive effect elements 114 and 124 is completed.

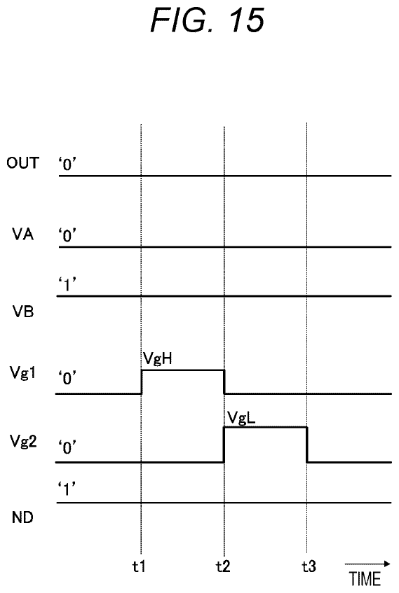

FIG. 15 is a timing chart illustrating a second example of the storing timing of the storage device according to the third embodiment. Note that, in the drawing, an example in which the second storing operation is performed after the first storing operation is performed is illustrated, but the first storing operation may be performed after the second storing operation is performed.

In the drawing, it is assumed that a logical value ‘0’ is retained in the volatile storage node N and a logical value ‘1’ is retained in the volatile storage node NB. At this time, the node voltage VA is set to 0 V, the node voltage VB is set to 1 V, and the output data OUT is set to a logical value ‘0’. Furthermore, the drive terminal ND is set to 1 V.

Next, the gate voltage Vg1 is set to VgH (t1). At this time, the first storing operation is performed, and the voltage controlled magnetoresistive effect element 124 is set to the high resistance state.

Next, after the gate voltage Vg1 is set to 0 V, the gate voltage Vg2 is set to VgL (t2). At this time, the second storing operation is performed, and the voltage controlled magnetoresistive effect element 114 is set to the low resistance state.

Next, the gate voltage Vg2 is set to 0 V (t3), and the storing of the forward logic from the latch circuit 102 to each of the voltage controlled magnetoresistive effect elements 114 and 124 is completed.

Note that, the restoring operation of the storage device 301 of the third embodiment is similar to the restoring operation of the storage device 101 of the above-described first embodiment.

As described above, in the above-described third embodiment, the pinned layer 141 of each of the voltage controlled magnetoresistive effect elements 114 and 124 is connected to the drive terminal ND. Then, at the time of restoring, the drive voltage is applied to the drive terminal ND such that the voltage of the pinned layer 141 of each of the voltage controlled magnetoresistive effect elements 114 and 124 is higher than the voltage of the free layer 143. Therefore, the data retained in the latch circuit 102 can be stored in the voltage controlled magnetoresistive effect elements 114 and 124 on the basis of voltage drive.

Furthermore, in a case where data is restored from each of the voltage controlled magnetoresistive effect elements 114 and 124 to the latch circuit 102, the voltage higher than the voltage applied to the pinned layer 141 of each of the voltage controlled magnetoresistive effect elements 114 and 124 is applied to the free layer 143. Therefore, a voltage can be applied such that the perpendicular magnetic anisotropy of each of the voltage controlled magnetoresistive effect elements 114 and 124 increases at the time of restoring. Thus, data can be restored from each of the voltage controlled magnetoresistive effect elements 114 and 124 to the latch circuit 102 without destroying the data retained in each of the voltage controlled magnetoresistive effect elements 114 and 124.

### 4. Fourth Embodiment

In the above-described third embodiment, the voltage controlled magnetoresistive effect elements 114 and 124 are provided in the latch circuit 102, the drive voltage is applied to the pinned layer 141 of each of the voltage controlled magnetoresistive effect elements 114 and 124, and the forward logic of the latch circuit 102 is stored. In a fourth embodiment, the voltage controlled magnetoresistive effect elements 114 and 124 are provided in the latch circuit 102, the drive voltage is applied to the pinned layer 141 of each of the voltage controlled magnetoresistive effect elements 114 and 124, and the reverse logic of the latch circuit 102 is stored.

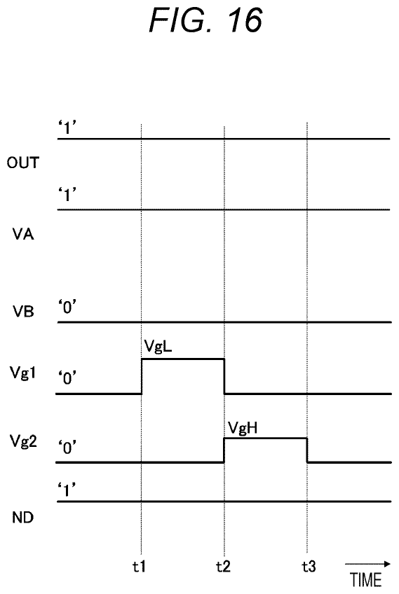

FIG. 16 is a timing chart illustrating a first example of a storing timing of a storage device according to the fourth embodiment. Note that, in the drawing, an example in which the second storing operation is performed after the first storing operation is performed is illustrated, but the first storing operation may be performed after the second storing operation is performed.

In the drawing, a configuration of the storage device of the fourth embodiment is similar to the configuration of the storage device 301 of the above-described third embodiment.

Here, it is assumed that a logical value ‘1’ is retained in the volatile storage node N and a logical value ‘0’ is retained in the volatile storage node NB. At this time, the node voltage VA is set to 1 V, the node voltage VB is set to 0 V, and the output data OUT is set to a logical value ‘1’. Furthermore, the drive terminal ND is set to 1 V.

Next, the gate voltage Vg1 is set to VgL (t1). At this time, the first storing operation is performed, and the voltage controlled magnetoresistive effect element 114 is set to the low resistance state.

Next, after the gate voltage Vg1 is set to 0 V, the gate voltage Vg2 is set to VgH (t2). At this time, the second storing operation is performed, and the voltage controlled magnetoresistive effect element 124 is set to the high resistance state.

Next, the gate voltage Vg2 is set to 0 V (t3), and the storing of the reverse logic from the latch circuit 102 to each of the voltage controlled magnetoresistive effect elements 114 and 124 is completed.

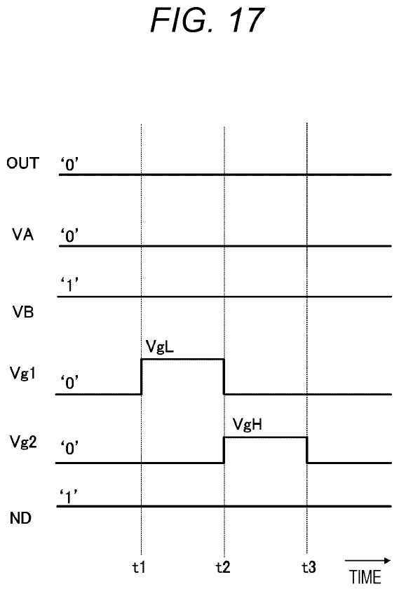

FIG. 17 is a timing chart illustrating a second example of the storing timing of the storage device according to the fourth embodiment. Note that, in the drawing, an example in which the second storing operation is performed after the first storing operation is performed is illustrated, but the first storing operation may be performed after the second storing operation is performed.

In the drawing, it is assumed that a logical value ‘0’ is retained in the volatile storage node N and a logical value ‘1’ is retained in the volatile storage node NB. At this time, the node voltage VA is set to 0 V, the node voltage VB is set to 1V, and the output data OUT is set to a logical value ‘0’. Furthermore, the drive terminal ND is set to 1 V.

Next, the gate voltage Vg1 is set to VgL (t1). At this time, the first storing operation is performed, and the voltage controlled magnetoresistive effect element 124 is set to the low resistance state.

Next, after the gate voltage Vg1 is set to 0 V, the gate voltage Vg2 is set to VgH (t2). At this time, the second storing operation is performed, and the voltage controlled magnetoresistive effect element 114 is set to the high resistance state.

Next, the gate voltage Vg2 is set to 0 V (t3), and the storing of the reverse logic from the latch circuit 102 to each of the voltage controlled magnetoresistive effect elements 114 and 124 is completed.

Note that, a restoring operation of the storage device of the fourth embodiment is similar to the restoring operation of the storage device of the above-described second embodiment.

As described above, in the above-described fourth embodiment, the pinned layer 141 of each of the voltage controlled magnetoresistive effect elements 114 and 124 is connected to the drive terminal ND. Then, at the time of restoring, the drive voltage is applied to the drive terminal ND such that the voltage of the pinned layer 141 of each of the voltage controlled magnetoresistive effect elements 114 and 124 is higher than the voltage of the free layer 143. Therefore, the data retained in the latch circuit 102 can be stored in the voltage controlled magnetoresistive effect elements 114 and 124 on the basis of voltage drive.

### 5. Fifth Embodiment

In the above-described first embodiment, the voltage controlled magnetoresistive effect elements 114 and 124 are provided in the latch circuit 102. In a fifth embodiment, the voltage controlled magnetoresistive effect elements 114 and 124 are provided in an SRAM.

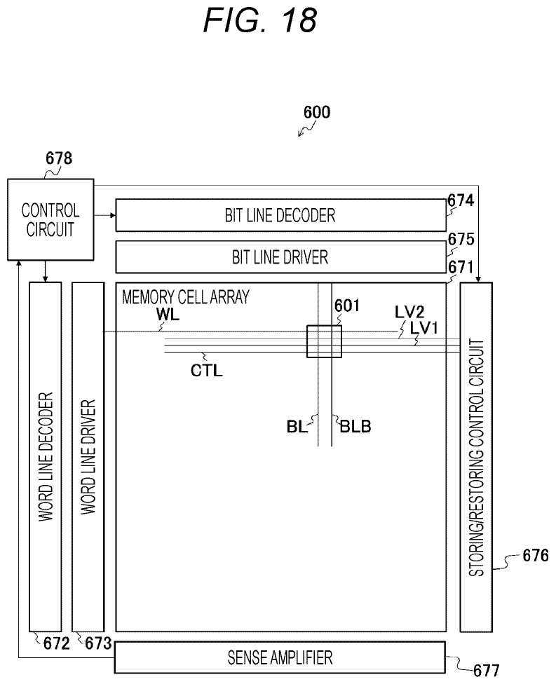

FIG. 18 is a diagram illustrating a configuration example of a storage device according to the fifth embodiment.

In the drawing, a storage device 600 includes a memory cell array 671, a word line decoder 672, a word line driver 673, a bit line decoder 674, and a bit line driver 675. Furthermore, the storage device 600 includes a storing/restoring control circuit 676, a sense amplifier 677, and a control circuit 678.

In the memory cell array 671, memory cells 601 are arranged in a matrix in a row direction and a column direction. A volatile storage unit and a nonvolatile storage unit are provided in each memory cell 601. The SRAM is provided as the volatile storage unit. The voltage controlled magnetoresistive effect elements 114 and 124 are provided as the nonvolatile storage unit. Th MOS transistors 113 and 123 are connected between the SRAM and the voltage controlled magnetoresistive effect elements 114 and 124, respectively. Furthermore, the MOS transistors 125 and 145 are connected between the SRAM and the voltage controlled magnetoresistive effect elements 114 and 124 with the inverters 115 and 135 interposed therebetween, respectively. At this time, each memory cell 601 can constitute a nonvolatile (NV) SRAM. Furthermore, in the memory cell array 671, the word line WL is provided for every row, and the bit lines BL and BLB are provided for every column. Moreover, gate voltage transmission lines LV1 and LV2 and a voltage drive line CTL are provided in the memory cell array 671. The gate voltage transmission line LV1 transmits the gate voltage Vg1 to the gates of the MOS transistors 113 and 123. The gate voltage transmission line LV2 transmits the gate voltage Vg2 to the gates of the MOS transistors 125 and 145. The voltage drive line CTL supplies a drive voltage used at the time of restoring and at the time of restoring to each of the voltage controlled magnetoresistive effect elements 114 and 124. Note that, in the following description, writing of data to the SRAM is referred to as writing, and reading of data from the SRAM is referred to as reading.

The word line decoder 672 interprets a command and a row address, and selects the word line WL to which a memory cell 601 to be a target of reading or writing is connected. The word line driver 673 drives the word line WL selected by the word line decoder 672.

The bit line decoder 674 interprets the command and the row address, and selects the bit lines BL and BLB to which a memory cell 601 to be a target of reading or writing is connected. The bit line driver 675 drives the bit lines BL and BLB selected by the bit line decoder 674.

The storing/restoring control circuit 676 controls storing and restoring for the memory cells 601 included in the memory cell array 671. At this time, the storing/restoring control circuit 676 applies the gate voltage Vg1 to the gate voltage transmission line LV1 when data is stored in one of the voltage controlled magnetoresistive effect elements 114 and 124 on the basis of data complementarily retained in the SRAM. Furthermore, the storing/restoring control circuit 676 applies the gate voltage Vg2 to the gate voltage transmission line LV2 when the data is stored in the other of the voltage controlled magnetoresistive effect elements 114 and 124 on the basis of the data complementarily retained in the SRAM. Furthermore, the storing/restoring control circuit 676 applies the drive voltage used at the time of storing and the time of restoring to the voltage drive line CTL.

The sense amplifier 677 detects data read from the memory cell array 671 on the basis of potentials of the bit lines BL and BLB selected by the bit line decoder 674. The control circuit 678 receives, as an input, the data detected by the sense amplifier 677 and controls operations of the bit line decoder 674, the word line decoder 672, and the storing/restoring control circuit 676.

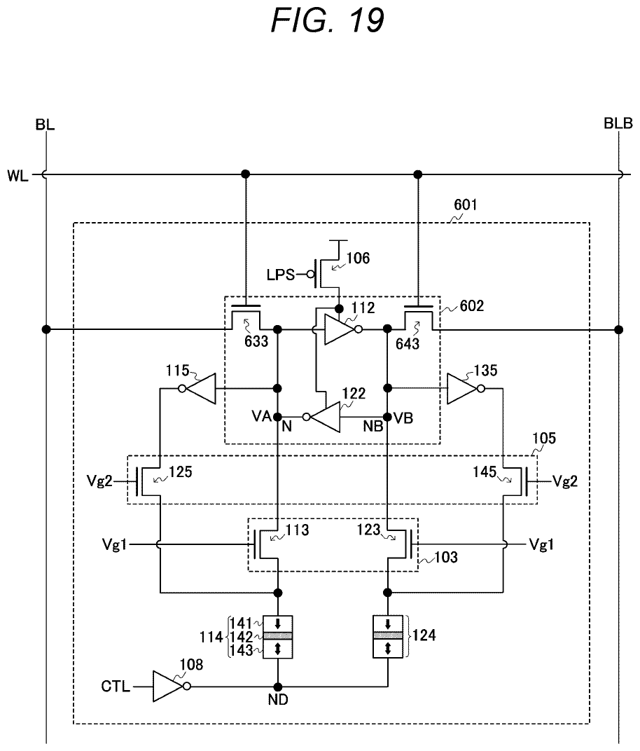

FIG. 19 is a diagram illustrating a configuration example of the memory cell of the storage device according to the fifth embodiment.

In the drawing, the memory cell 601 includes an SRAM 602 instead of the latch circuit 102 of the above-described first embodiment. Note that, the SRAM 602 is an example of a volatile storage unit described in the claims.

The SRAM 602 complementarily retains data. At this time, the SRAM 602 operates as a bistable circuit and can retain the data in a volatile manner. The SRAM 602 includes the volatile storage nodes N and NB that complementarily retain the data. Each of the volatile storage nodes N and NB retains the data in a volatile manner.

In the SRAM 602, access transistors 633 and 643 are added to the latch circuit 102. The access transistors 633 and 643 may be MOS transistors. The access transistor 633 is connected between the bit line BL and the volatile storage node N. The access transistor 643 is connected between the bit line BLB and the volatile storage node NB. Gates of the access transistors 633 and 643 are connected to the word line WL.

The voltage controlled magnetoresistive effect element 114 is connected to the volatile storage node N of the SRAM 602 with the MOS transistor 113 interposed therebetween. Furthermore, the voltage controlled magnetoresistive effect element 114 is connected to the volatile storage node N of the SRAM 602 with the MOS transistor 125 interposed therebetween. At this time, the inverter 115 is interposed between the volatile storage node N and the MOS transistor 125. The voltage controlled magnetoresistive effect element 124 is connected to the volatile storage node NB of the SRAM 602 with the MOS transistor 123 interposed therebetween. Furthermore, the voltage controlled magnetoresistive effect element 124 is connected to the volatile storage node NB of the SRAM 602 with the MOS transistor 145 interposed therebetween. At this time, the inverter 135 is interposed between the volatile storage node NB and the MOS transistor 145. The free layer 143 of each of the voltage controlled magnetoresistive effect elements 114 and 124 is connected to the drive terminal ND. The drive voltage is applied to the drive terminal ND via the voltage drive line CTL. The gate voltage Vg1 is applied to the gates of the MOS transistors 113 and 123 via the gate voltage transmission line LV1. The gate voltage Vg2 is applied to the gates of the MOS transistors 125 and 145 via the gate voltage transmission line LV2.

As described above, in the above-described fifth embodiment, the voltage controlled magnetoresistive effect elements 114 and 124 are provided in each memory cell 601 including the SRAM 602. Therefore, it is possible to add the nonvolatile storage function to the SRAM while suppressing an increase in power consumption when the data retained in the SRAM is stored in the voltage controlled magnetoresistive effect elements 114 and 124.

Note that, in the above-described fifth embodiment, an example in which the SRAM 602 is provided instead of the latch circuit 102 of the above-described first embodiment has been described. However, the SRAM 602 may be provided instead of the latch circuit 102 of the above-described second embodiment. Furthermore, the SRAM 602 may be provided instead of the latch circuit 102 of the above-described third embodiment, or the SRAM 602 may be provided instead of the latch circuit 102 of the above-described fourth embodiment.

Note that, the above-described embodiments show examples for embodying the present technology, and the respective matters in the embodiments and the respective matters specifying the invention in the claims have correspondence relationships. Similarly, the respective matters specifying the invention in the claims and the respective matters with the same names in the embodiments of the present technology have correspondence relationships. The present technology, however, is not limited to the embodiments, and can be implemented by making various modifications to the embodiments without departing from the scope of the present technology. Furthermore, effects described in the present specification are merely examples and are not restrictive, and some other effects may be achieved.

Note that, the present technology may also have the following configurations.

(1) A storage device including
a volatile storage unit that complementarily retains data,
a voltage controlled magnetoresistive effect element that retains the data complementarily retained in the volatile storage unit,
a first variable resistance element that is connected between the volatile storage unit and the voltage controlled magnetoresistive effect element and has a variable resistance between the volatile storage unit and the voltage controlled magnetoresistive effect element, and
a second variable resistance element that is connected between the volatile storage unit and the voltage controlled magnetoresistive effect element with an inverter interposed therebetween and has a variable resistance between the volatile storage unit and the voltage controlled magnetoresistive effect element.

(2) The storage device according to the above (1), in which the second variable resistance element and the inverter are connected in series, and a series circuit of the second variable resistance element and the inverter is connected in parallel with the first variable resistance element.

(3) The storage device according to the above (1) or (2), in which each of the first variable resistance element and the second variable resistance element changes a resistance such that cell voltages applied to the voltage controlled magnetoresistive effect element become substantially equal to each other between when the voltage controlled magnetoresistive effect element transitions from a high resistance state to a low resistance state and when the voltage controlled magnetoresistive effect element transitions from the low resistance state to the high resistance state.

(4) The storage device according to any one of the above (1) to (3),
in which the first variable resistance element includes a first field effect transistor of which an on-resistance changes on a basis of a first gate voltage, and
the second variable resistance element includes a second field effect transistor of which an on-resistance changes on a basis of a second gate voltage.

(5) The storage device according to any one of the above (1) to (4),
in which the first field effect transistor is used not only as the first variable resistance element but also as a storing transistor that stores data from the volatile storage unit to the voltage controlled magnetoresistive effect element and a restoring transistor that restores data from the voltage controlled magnetoresistive effect element to the volatile storage unit.

(6) The storage device according to any one of the above (1) to (5),
in which the voltage controlled magnetoresistive effect element includes a first voltage controlled magnetoresistive effect element and a second voltage controlled magnetoresistive effect element in which resistance states different from each other are set in accordance with the data complementarily retained in the volatile storage unit.

(7) The storage device according to the above (6),
in which, in a case where the first voltage controlled magnetoresistive effect element is written with a high resistance on a basis of a first gate voltage applied to the first field effect transistor, the second voltage controlled magnetoresistive effect element is written with a low resistance on a basis of a second gate voltage applied to the second field effect transistor.

(8) The storage device according to the above (7),
in which, in a case where the first voltage controlled magnetoresistive effect element is in a low resistance state when high-resistance writing is performed, a reversal voltage for reversing a magnetization direction of the first voltage controlled magnetoresistive effect element is applied to the first voltage controlled magnetoresistive effect element on a basis of the first gate voltage,
in a case where the first voltage controlled magnetoresistive effect element is in a high resistance state when high-resistance writing is performed, a voltage higher than the reversal voltage is applied to the first voltage controlled magnetoresistive effect element on a basis of the first gate voltage,
in a case where the second voltage controlled magnetoresistive effect element is in a high resistance state when low-resistance writing is performed, a reversal voltage for reversing a magnetization direction of the second voltage controlled magnetoresistive effect element is applied to the second voltage controlled magnetoresistive effect element on a basis of the second gate voltage, and
in a case where the second voltage controlled magnetoresistive effect element is in a low resistance state when low-resistance writing is performed, a voltage lower than the reversal voltage is applied to the second voltage controlled magnetoresistive effect element on a basis of the second gate voltage.

(9) The storage device according to the above (6),
in which, in a case where the first voltage controlled magnetoresistive effect element is written with a low resistance on a basis of a first gate voltage applied to the first field effect transistor, the second voltage controlled magnetoresistive effect element is written with a high resistance on a basis of a second gate voltage applied to the second field effect transistor.

(10) The storage device according to the above (9),
in which, in a case where the first voltage controlled magnetoresistive effect element is in a high resistance state when low-resistance writing is performed, a reversal voltage for reversing a magnetization direction of the first voltage controlled magnetoresistive effect element is applied to the first voltage controlled magnetoresistive effect element on a basis of the first gate voltage,
in a case where the first voltage controlled magnetoresistive effect element is in a low resistance state when low-resistance writing is performed, a voltage lower than the reversal voltage is applied to the first voltage controlled magnetoresistive effect element on a basis of the first gate voltage,
in a case where the second voltage controlled magnetoresistive effect element is in a low resistance state when high-resistance writing is performed, a reversal voltage for reversing a magnetization direction of the second voltage controlled magnetoresistive effect element is applied to the second voltage controlled magnetoresistive effect element on a basis of the second gate voltage, and
in a case where the second voltage controlled magnetoresistive effect element is in a high resistance state when high-resistance writing is performed, a voltage higher than the reversal voltage is applied to the second voltage controlled magnetoresistive effect element on a basis of the second gate voltage.

(11) The storage device according to any one of the above (1) to (10),
in which each of the first voltage controlled magnetoresistive effect element and the second voltage controlled magnetoresistive effect element includes
a pinned layer having a fixed magnetization direction,
a free layer capable of reversing a magnetization direction of magnetism induced on a basis of a voltage, and
a tunnel barrier layer sandwiched between the pinned layer and the free layer.

(12) The storage device according to the above (11),
in which, in a case where data is stored from the volatile storage unit to the voltage controlled magnetoresistive effect element,
a drive voltage is applied to the free layer of the first voltage controlled magnetoresistive effect element such that the reversal voltage is applied when the first gate voltage is applied to the first field effect transistor,
the drive voltage is applied to the free layer of the second voltage controlled magnetoresistive effect element such that the reversal voltage is applied when the second gate voltage is applied to the second field effect transistor, and
in a case where data is restored from the voltage controlled magnetoresistive effect element to the volatile storage unit,
a voltage lower than a voltage applied to the pinned layer is applied to the free layer.

(13) The storage device according to the above (11) or (12),
in which, in a case where data is stored from the volatile storage unit to the voltage controlled magnetoresistive effect element,
a drive voltage is applied to the pinned layer of the first voltage controlled magnetoresistive effect element such that the reversal voltage is applied when the first gate voltage is applied to the first field effect transistor,
the drive voltage is applied to the pinned layer of the second voltage controlled magnetoresistive effect element such that the reversal voltage is applied when the second gate voltage is applied to the second field effect transistor, and
in a case where data is restored from the voltage controlled magnetoresistive effect element to the volatile storage unit,
a voltage lower than a voltage applied to the free layer is applied to the pinned layer.

(14) The storage device according to the above (12) or (13), in which, in a case where data is stored from the volatile storage unit to the voltage controlled magnetoresistive effect element, the drive voltage is set such that voltages in a same direction are applied to the first voltage controlled magnetoresistive effect element and the second voltage controlled magnetoresistive effect element.

(15) The storage device according to any one of the above (1) to (14),
further including a power gating transistor that performs power gating of the inverter.

(16) The storage device according to any one of the above (1) to (15),
in which the volatile storage unit is a latch circuit.

(17) The storage device according to any one of the above (1) to (15),
in which the volatile storage unit is a static random access memory (SRAM).

### REFERENCE SIGNS LIST

101 Storage device
102 Latch circuit
112, 122 Inverter
103, 105 Variable resistance circuit
113, 123, 125, 145 MOS transistor
114, 124 Voltage controlled magnetoresistive effect element
141 Pinned layer
142 Tunnel barrier layer
143 Free layer
115, 135, 107, 108 Inverter
106 Power gating transistor
N, NB Volatile storage node
ND Drive terminal

1. A storage device comprising:
a volatile storage unit that complementarily retains data;
a voltage controlled magnetoresistive effect element that retains the data complementarily retained in the volatile storage unit;
a first variable resistance element that is connected between the volatile storage unit and the voltage controlled magnetoresistive effect element and has a variable resistance between the volatile storage unit and the voltage controlled magnetoresistive effect element; and
a second variable resistance element that is connected between the volatile storage unit and the voltage controlled magnetoresistive effect element with an inverter interposed therebetween and has a variable resistance between the volatile storage unit and the voltage controlled magnetoresistive effect element.

2. The storage device according to claim 1,
wherein the second variable resistance element and the inverter are connected in series, and a series circuit of the second variable resistance element and the inverter is connected in parallel with the first variable resistance element.

3. The storage device according to claim 2,
wherein each of the first variable resistance element and the second variable resistance element changes a resistance such that cell voltages applied to the voltage controlled magnetoresistive effect element become substantially equal to each other between when the voltage controlled magnetoresistive effect element transitions from a high resistance state to a low resistance state and when the voltage controlled magnetoresistive effect element transitions from the low resistance state to the high resistance state.

4. The storage device according to claim 2,
wherein the first variable resistance element includes a first field effect transistor of which an on-resistance changes on a basis of a first gate voltage, and
the second variable resistance element includes a second field effect transistor of which an on-resistance changes on a basis of a second gate voltage.

5. The storage device according to claim 4,
wherein the first field effect transistor is used not only as the first variable resistance element but also as a storing transistor that stores data from the volatile storage unit to the voltage controlled magnetoresistive effect element and a restoring transistor that restores data from the voltage controlled magnetoresistive effect element to the volatile storage unit.

6. The storage device according to claim 1,
wherein the voltage controlled magnetoresistive effect element includes a first voltage controlled magnetoresistive effect element and a second voltage controlled magnetoresistive effect element in which resistance states different from each other are set in accordance with the data complementarily retained in the volatile storage unit.

7. The storage device according to claim 6,
wherein, in a case where the first voltage controlled magnetoresistive effect element is written with a high resistance on a basis of a first gate voltage applied to the first field effect transistor, the second voltage controlled magnetoresistive effect element is written with a low resistance on a basis of a second gate voltage applied to the second field effect transistor.

8. The storage device according to claim 7,
wherein, in a case where the first voltage controlled magnetoresistive effect element is in a low resistance state when high-resistance writing is performed, a reversal voltage for reversing a magnetization direction of the first voltage controlled magnetoresistive effect element is applied to the first voltage controlled magnetoresistive effect element on a basis of the first gate voltage,
in a case where the first voltage controlled magnetoresistive effect element is in a high resistance state when high-resistance writing is performed, a voltage higher than the reversal voltage is applied to the first voltage controlled magnetoresistive effect element on a basis of the first gate voltage,
in a case where the second voltage controlled magnetoresistive effect element is in a high resistance state when low-resistance writing is performed, a reversal voltage for reversing a magnetization direction of the second voltage controlled magnetoresistive effect element is applied to the second voltage controlled magnetoresistive effect element on a basis of the second gate voltage, and
in a case where the second voltage controlled magnetoresistive effect element is in a low resistance state when low-resistance writing is performed, a voltage lower than the reversal voltage is applied to the second voltage controlled magnetoresistive effect element on a basis of the second gate voltage.

9. The storage device according to claim 6,
wherein, in a case where the first voltage controlled magnetoresistive effect element is written with a low resistance on a basis of a first gate voltage applied to the first field effect transistor, the second voltage controlled magnetoresistive effect element is written with a high resistance on a basis of a second gate voltage applied to the second field effect transistor.

10. The storage device according to claim 9,
wherein, in a case where the first voltage controlled magnetoresistive effect element is in a high resistance state when low-resistance writing is performed, a reversal voltage for reversing a magnetization direction of the first voltage controlled magnetoresistive effect element is applied to the first voltage controlled magnetoresistive effect element on a basis of the first gate voltage,
in a case where the first voltage controlled magnetoresistive effect element is in a low resistance state when low-resistance writing is performed, a voltage lower than the reversal voltage is applied to the first voltage controlled magnetoresistive effect element on a basis of the first gate voltage,
in a case where the second voltage controlled magnetoresistive effect element is in a low resistance state when high-resistance writing is performed, a reversal voltage for reversing a magnetization direction of the second voltage controlled magnetoresistive effect element is applied to the second voltage controlled magnetoresistive effect element on a basis of the second gate voltage, and
in a case where the second voltage controlled magnetoresistive effect element is in a high resistance state when high-resistance writing is performed, a voltage higher than the reversal voltage is applied to the second voltage controlled magnetoresistive effect element on a basis of the second gate voltage.

11. The storage device according to claim 7,
wherein each of the first voltage controlled magnetoresistive effect element and the second voltage controlled magnetoresistive effect element includes
a pinned layer having a fixed magnetization direction,
a free layer capable of reversing a magnetization direction of magnetism induced on a basis of a voltage, and
a tunnel barrier layer sandwiched between the pinned layer and the free layer.

12. The storage device according to claim 11,
wherein, in a case where data is stored from the volatile storage unit to the voltage controlled magnetoresistive effect element,
a drive voltage is applied to the free layer of the first voltage controlled magnetoresistive effect element such that the reversal voltage is applied when the first gate voltage is applied to the first field effect transistor,
the drive voltage is applied to the free layer of the second voltage controlled magnetoresistive effect element such that the reversal voltage is applied when the second gate voltage is applied to the second field effect transistor, and
in a case where data is restored from the voltage controlled magnetoresistive effect element to the volatile storage unit,
a voltage lower than a voltage applied to the pinned layer is applied to the free layer.

13. The storage device according to claim 11,
wherein, in a case where data is stored from the volatile storage unit to the voltage controlled magnetoresistive effect element,
a drive voltage is applied to the pinned layer of the first voltage controlled magnetoresistive effect element such that the reversal voltage is applied when the first gate voltage is applied to the first field effect transistor,
the drive voltage is applied to the pinned layer of the second voltage controlled magnetoresistive effect element such that the reversal voltage is applied when the second gate voltage is applied to the second field effect transistor, and
in a case where data is restored from the voltage controlled magnetoresistive effect element to the volatile storage unit,
a voltage lower than a voltage applied to the free layer is applied to the pinned layer.

14. The storage device according to claim 12,
wherein, in a case where data is stored from the volatile storage unit to the voltage controlled magnetoresistive effect element,
the drive voltage is set such that voltages in a same direction are applied to the first voltage controlled magnetoresistive effect element and the second voltage controlled magnetoresistive effect element.

15. The storage device according to claim 1, further comprising:
a power gating transistor that performs power gating of the inverter.

16. The storage device according to claim 1,
wherein the volatile storage unit is a latch circuit.

17. The storage device according to claim 1,
wherein the volatile storage unit is a static random access memory (SRAM).
